(19) United States
(12) Patent Application Publication
(10) Pub. No.: US 2013/0147492 A1
(43) Pub. Date: Jun. 13, 2013

(54) POWER CONSUMPTION MEASURING DEVICE

(71) Applicants: CHING-LIN HSIEH, NEW TAIPEI CITY (TW); CHING-FENG HSIEH, TAIPEI CITY (TW)

(72) Inventors: CHING-LIN HSIEH, NEW TAIPEI CITY (TW); CHING-FENG HSIEH, TAIPEI CITY (TW)

(73) Assignees: ASKEY COMPUTER CORP., (TW); ASKEY TECHNOLOGY (JIANGSU) LTD., (CN)

(21) Appl. No.: 13/362,004

(22) Filed: Jan. 31, 2012

(30) Foreign Application Priority Data
Dec. 13, 2011 (TW) 100146020

(51) Int. Cl. G01R 35/04

(52) U.S. Cl. 324/601

(57) ABSTRACT

A power consumption measuring device includes an analog-to-digital converter and an arithmetic unit and serves to convert a current signal supplied to a load into a measurement digital signal by the analog-to-digital converter, send the measurement digital signal to the arithmetic unit for measuring a power consumption level of the load. The power consumption measuring device is characterized in that: the arithmetic unit selects a current gain value and a correction compensation value based on a current range into which the measurement digital signal falls and adapted to adjust a gain value of the analog-to-digital converter for reducing an error rate and enhancing accuracy of the next measurement digital signal.

### CROSS-REFERENCE TO RELATED APPLICATION

This non-provisional application claims priority under 35 U.S.C. §119(a) on Patent Application No(s). 100146020 filed in Taiwan, R.O.C. on Dec. 13, 2011, the entire contents of which are hereby incorporated by reference.

### FIELD OF TECHNOLOGY

The present invention relates to measurement devices, and more particularly, to a power consumption measuring device for use with an electronic product.

### BACKGROUND

The power consumption of an electronic product is of vital importance to designers and consumers. The power consumption of an electronic product is seen by designers (developers) as a yardstick for evaluation of a product being designed and thus is a factor in the consumers' willingness to purchase the product and is even, after the purchase, a criterion against which the consumers judge whether the product is malfunctioning or not.

The power (in watt) consumed by an electronic product functioning well is a constant value. Abnormal levels of power consumption of the electronic product indicate that the electronic product has been damaged and needs timely maintenance in order to ensure user safety.

A conventional power consumption measuring device is usually applicable to a range of input current. However, different electronic products do not necessarily use the same current value, and sometimes the difference in current value therebetween is great. Even if the conventional power consumption measuring device operates within an appropriate range of input current while measuring the current of different electronic products, measurement of the current value is unlikely to be accurate. For example, given a low current of an electronic product, the power consumption measuring device can still detect and measure the low current of the electronic product, but does so inaccurately.

### SUMMARY

It is an objective of the present invention to reduce an error rate of measurement and enhance the accuracy of measurement.

In order to achieve the above and other objectives, the present invention provides a power consumption measuring device comprising an analog-to-digital converter and an arithmetic unit and adapted to convert an electrical signal supplied to a load into a measurement digital signal by means of the analog-to-digital converter and send the measurement digital signal to the arithmetic unit for measuring a power consumption level of the load. The power consumption measuring device being characterized in that the arithmetic unit comprises: a gain adjustment unit configured with at least two current gain values each corresponding to a current range; a correction unit having at least two correction compensation values defined by the at least two current gain values, respectively, and defined in order to eliminate an internal impedance of the power consumption measuring device while being corresponding to the current gain values, respectively; and a control unit connected to the gain adjustment unit and the correction unit for configuring the current ranges corresponding to the current gain values, respectively, and selecting the current gain values and the correction compensation values based on the current range into which the measurement digital signal falls, so as to adjust the gain value of the analog-to-digital converter.

In an embodiment, the gain adjustment unit provides a first current gain value and a second current gain value and provides a first correction compensation value and a second correction compensation value which correspond to the first current gain value and the second current gain value, respectively. The second current gain value and the second correction compensation value are greater than the first current gain value and the first correction compensation value, respectively. The control unit sets two adjacent ones of the current ranges to one above a current threshold value and another one below the current threshold value. The control unit selects the first current gain value and the first correction compensation value whenever the measurement digital signal falls into the current range below the current threshold value.

In an embodiment, the control unit sets the current threshold value to 500 mA.

Accordingly, the power consumption measuring device of the present invention assigns current gain values and a correction compensation value to a high distortion range susceptible to non-linear measurement results, thereby enhancing the accuracy of the current values measured.

### BRIEF DESCRIPTION

Objectives, features, and advantages of the present invention are hereunder illustrated with specific embodiments in conjunction with the accompanying drawings, in which:

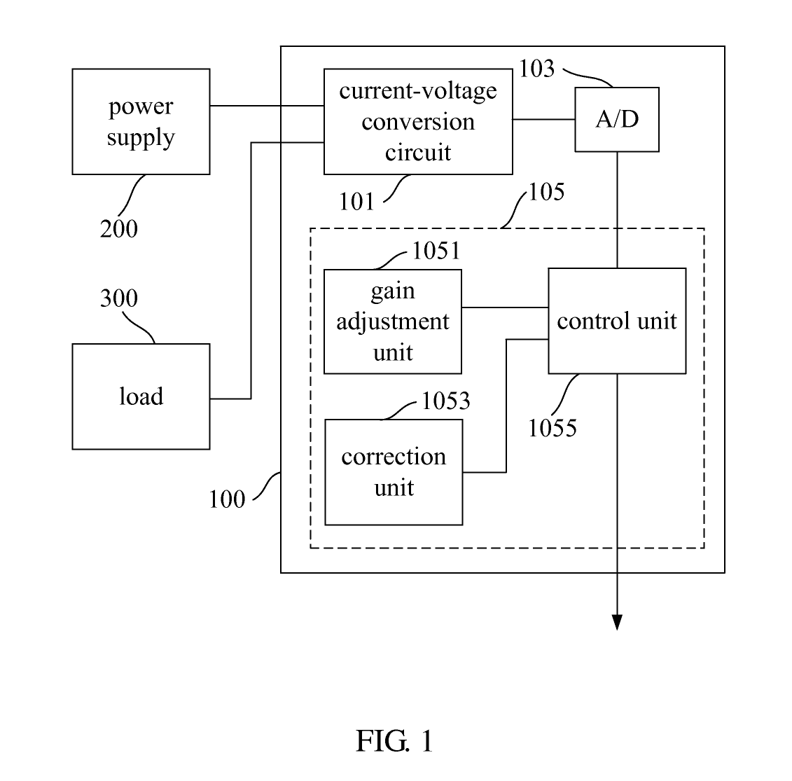

FIG. 1 is a functional block diagram of a power consumption measuring device according to an embodiment of the present invention.

### DETAILED DESCRIPTION

Referring to FIG. 1, there is shown a functional block diagram of a power consumption measuring device 100 according to an embodiment of the present invention. The power consumption measuring device 100 is usually series-connected between a power supply 200 and a load 300 for converting an electrical signal supplied to the load 300 into a measurement digital signal by means of an analog-to-digital converter 103 of the power consumption measuring device 100 and then sending the measurement digital signal to an arithmetic unit 105 of the power consumption measuring device 100 for measuring the power consumption level of the load 300. A current-voltage conversion circuit 101 is disposed between the analog-to-digital converter 103 and the power supply 200 and disposed between the analog-to-digital converter 103 and the load 300. The current-voltage conversion circuit 101 converts the electrical signal supplied to the load 300 into an input signal required for the analog-to-digital converter 103. The input signal is an analog signal.

The analog-to-digital converter 103 of the power consumption measuring device 100 performs A/D conversion on the analog signal received. In an embodiment of the present invention, to enhance measurement precision, it is necessary that a gain value of the analog-to-digital converter 103 is dynamically configured based on the input electrical signal. Hence, the gain value serves as the basis of adjustment during the first instance of measurement performed by the power consumption measuring device 100, whereas the adjusted gain value and correction value together serve as the basis of adjustment during the second instance of measurement performed by the power consumption measuring device 100.

The arithmetic unit 105 performs computation on the measurement digital signal generated by the analog-to-digital converter 103, and then adjusts the initial measurement value according to the preset gain value and correction value before outputting the adjusted measurement signal.

Referring to FIG. 1, the arithmetic unit 105 comprises a gain adjustment unit 1051, a correction unit 1053, and a control unit 1055.

The gain adjustment unit 1051 has at least two current gain values to be selected for use in adjustment. Each of the current gain values corresponds to one of the different current ranges of the measurement digital signal measured.

The correction unit 1053 has at least two correction compensation values defined in accordance with the at least two current gain values, respectively. To eliminate the internal impedance of the power consumption measuring device 100, it is necessary that the correction compensation values of the power consumption measuring device 100 have to be configured beforehand. The correction compensation values are defined in accordance with the current gain values, respectively.

The control unit 1055 is connected to the gain adjustment unit 1051 and the correction unit 1053. The control unit 1055 configures the current ranges corresponding to the current gain values respectively, and selects the current gain values and the correction compensation values from the gain adjustment unit 1051 and the correction unit 1053 based on the current range into which the measurement digital signal falls, so as to adjust the gain value of the analog-to-digital converter 103. Afterward, during the next instance of measurement, the measurement digital signal is calculated according to the current gain values and the correction compensation values which have been adjusted, thereby attaining accurate measurement results.

In an embodiment, the gain adjustment unit 1051 provides two gain values, namely a first current gain value and a second current gain value. The correction unit 1053 assigns a first correction compensation value and a second correction compensation value to the first current gain value and the second current gain value. The second current gain value and the second correction compensation value are greater than the first current gain value and the first correction compensation value, respectively. The control unit 1055 distinguishes the current ranges based on a current threshold value, such that two adjacent ones of the current ranges are defined by the current threshold value, that is, one above the current threshold value, and the other one below the current threshold value. During the first instance of measurement, the control unit 1055 selects the first current gain value and the first correction compensation value whenever the measurement digital signal falls into the current range below the current threshold value. In this embodiment, the current threshold value is set to 500 mA, for example.

Hence, not only is the gain value used by the analog-to-digital converter 103 dynamically adjusted, but the accurate gain value and the correction compensation value corresponding thereto are automatically selected based on a variation in the ranges of measurement signals, thereby attaining accurate measurement results. It is also feasible that the analog-to-digital converter 103 and the arithmetic unit 105 are integrated to become a logical circuit for implementing the present invention.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A power consumption measuring device comprising an analog-to-digital converter and an arithmetic unit and adapted to convert an electrical signal supplied to a load into a measurement digital signal by means of the analog-to-digital converter and send the measurement digital signal to the arithmetic unit for measuring a power consumption level of the load, the power consumption measuring device being characterized in that the arithmetic unit comprises:
a gain adjustment unit configured with at least two current gain values each corresponding to a current range;
a correction unit having at least two correction compensation values defined by the at least two current gain values, respectively, and defined in order to eliminate an internal impedance of the power consumption measuring device while being corresponding to the current gain values, respectively; and
a control unit connected to the gain adjustment unit and the correction unit for configuring the current ranges corresponding to the current gain values, respectively, and selecting the current gain values and the correction compensation values based on the current range into which the measurement digital signal falls, so as to adjust the gain value of the analog-to-digital converter.

2. The power consumption measuring device of claim 1, wherein the gain adjustment unit provides a first current gain value and a second current gain value and provides a first correction compensation value and a second correction compensation value which correspond to the first current gain value and the second current gain value, respectively, wherein the second current gain value and the second correction compensation value are greater than the first current gain value and the first correction compensation value, respectively, wherein the control unit sets two adjacent ones of the current ranges to one above a current threshold value and another one below the current threshold value, wherein the control unit selects the first current gain value and the first correction compensation value whenever the measurement digital signal falls into the current range below the current threshold value.

3. The power consumption measuring device of claim 2, wherein the control unit sets the current threshold value to 500 mA.
